(19) United States
(12) Patent Application Publication
(10) Pub. No.: US 2014/0151101 A1
(43) Pub. Date: Jun. 5, 2014

(54) EMBEDDED MULTILAYER CERAMIC ELECTRONIC COMPONENT AND METHOD OF MANUFACTURING THE SAME, AND PRINTED CIRCUIT BOARD HAVING EMBEDDED MULTILAYER CERAMIC ELECTRONIC COMPONENT THEREIN

(71) Applicant: SAMSUNG ELECTRO-MECHANICS CO., LTD., Suwon (KR)

(72) Inventors: Hai Joon LEE, Suwon (KR); Byoung Hwa LEE, Suwon (KR); Jin Man JUNG, Suwon (KR)

(73) Assignee: SAMSUNG ELECTRO-MECHANICS CO., LTD., Suwon (KR)

(21) Appl. No.: 13/770,971

(22) Filed: Feb. 19, 2013

(30) Foreign Application Priority Data
Dec. 4, 2012 (KR) 10-2012-0139623

(51) Int. Cl. H01G 4/12; H05K 1/18; H01G 4/30

(52) U.S. Cl. CPC H01G 4/12; H01G 4/30; H05K 1/182
USPC 174/260; 361/301.4; 156/89.12

(57) ABSTRACT

There is provided an embedded multilayer ceramic electronic component, including: a ceramic body including dielectric layers; first and second internal electrodes facing each other with the dielectric layers interposed therebetween; a first external electrode and a second external electrode formed on external surfaces of the ceramic body, the first external electrode being electrically connected to the first internal electrodes and the second external electrode being electrically connected to the second internal electrodes; and a plating layer formed on the first external electrode and the second external electrode, wherein a surface roughness of the ceramic body is 500 nm or greater and not greater than a thickness of a ceramic cover sheet and a surface roughness of the plating layer is 300 nm or greater and not greater than a thickness of the plating layer.

### CROSS-REFERENCE TO RELATED APPLICATIONS

This application claims the priority of Korean Patent Application No. 10-2012-0139623 filed on Dec. 4, 2012, in the Korean Intellectual Property Office, the disclosure of which is incorporated herein by reference.

### BACKGROUND OF THE INVENTION

1. Field of the Invention

The present invention relates to an embedded multilayer ceramic electronic component and a method of manufacturing the same, and a printed circuit board having the embedded multilayer ceramic electronic component therein.

2. Description of the Related Art

As electronic circuits are provided with higher levels of density and integration, space provided for mounting passive elements on a printed circuit board may be insufficient. In order to solve this problem, attempts at realizing components embedded in boards, that is, embedded devices, are being made. In particular, various methods of embedding multilayer ceramic electronic components in the board for use as capacitive components are suggested.

In order to embed multilayer ceramic electronic components in the board, there is provided a method in which a board material itself is used as a dielectric material for the multilayer ceramic electronic component and copper wiring or the like is used as an electrode for the multilayer ceramic electronic component. In addition, in order to realize embedded multilayer ceramic electronic components, there are provided a method in which a high-dielectric polymer sheet or a thin film of dielectric is formed inside the board to thereby manufacture the embedded multilayer ceramic electronic component, a method of embedding the multilayer ceramic electronic component in the board, and the like.

Generally, a multilayer ceramic electronic component includes a plurality of dielectric layers formed of a ceramic material and internal electrodes interposed between the plurality of dielectric layers. An embedded multilayer ceramic electronic component having high capacitance may be realized by disposing this multilayer ceramic electronic component inside the board.

In order to manufacture a printed circuit board including an embedded multilayer ceramic electronic component, portions of an upper laminated layer and a lower laminated layer need to be removed with a laser to form a via hole to thereby connect a substrate wiring and an external electrode of the multilayer ceramic electronic component, after the multilayer ceramic electronic component is embedded in a core substrate. This laser process may significantly increase manufacturing costs in a printed circuit board manufacturing process.

In the procedure of embedding the embedded multilayer ceramic electronic component in the board, an epoxy resin is hardened and a thermal treatment for crystallization of metal electrodes is performed thereon. In this case, defects in an adhesive surface between the board and the multilayer ceramic electronic component may occur due to differences in coefficients of thermal expansion (CTE) between the epoxy resin, the metal electrode, the ceramic material of the multilayer ceramic electronic component, and the like, or through thermal expansion of the board. These defects may cause faults, such as delamination of the adhesive surface, during a reliability test.

### RELATED ART DOCUMENTS

### Patent Documents

(Patent Document 1) Korean Patent Laid-Open Publication No. 2006-0098771
(Patent Document 2) Korean Patent Laid-Open Publication No. 2006-0134277

### SUMMARY OF THE INVENTION

An aspect of the present invention provides an embedded multilayer ceramic electronic component, capable of improving delamination between a multilayer ceramic electronic component and a board and thus enhancing adhesive characteristics thereof, by controlling surface roughness of a ceramic surface of the multilayer ceramic electronic component and surface roughness of the plating layer, a method of manufacturing the embedded multilayer ceramic electronic component, and a printed circuit board having the embedded multilayer ceramic electronic component therein.

According to an aspect of the present invention, there is provided an embedded multilayer ceramic electronic component, including: a ceramic body including dielectric layers; first and second internal electrodes facing each other with the dielectric layers interposed therebetween; a first external electrode and a second external electrode formed on external surfaces of the ceramic body, the first external electrode being electrically connected to the first internal electrodes and the second external electrode being electrically connected to the second internal electrodes; and a plating layer formed on the first external electrode and the second external electrode, wherein a surface roughness of the ceramic body is 500 nm or greater and not greater than a thickness of a ceramic cover sheet and a surface roughness of the plating layer is 300 nm or greater and not greater than a thickness of the plating layer.

The surface roughness of the ceramic body may be 700 nm or greater and not greater than the thickness of the ceramic cover sheet.

The surface roughness of the plating layer may be 500 nm or greater and not greater than the thickness of the plating layer.

The thickness of the ceramic cover sheet may be 1 μm or greater and not greater than 30 μm.

The thickness of the plating layer may be greater than 4 μm and smaller than 15 μm.

According to another aspect of the present invention, there is provided a method of manufacturing an embedded multilayer ceramic electronic component, the method including: preparing ceramic green sheets including dielectric layers; forming internal electrode patterns on the ceramic green sheets by using a conductive paste for internal electrodes containing a conductive metal powder and a ceramic powder; laminating the ceramic green sheets having the internal electrode patterns formed thereon, to thereby form a ceramic body including first internal electrodes and second internal electrodes facing each other therein; placing sandpaper on each of an upper surface and a lower surface of the ceramic body and performing compressing thereon; removing the sandpaper from the ceramic body and firing the ceramic body; forming a first external electrode and a second external electrode on the upper and lower surfaces and end surfaces of the ceramic body; forming a plating layer on the first external electrode and the second external electrode; and applying a sand blasting method to the ceramic body and the plating layer formed on the first external electrode and the second external electrode to control surface roughnesses thereof, wherein the surface roughness of the ceramic body is 500 nm or greater and not greater than a thickness of a ceramic cover sheet and the surface roughness of the plating layer is 300 nm or greater and not greater than a thickness of the plating layer.

The surface roughness of the ceramic body may be 700 nm or greater and not greater than the thickness of the ceramic cover sheet.

The surface roughness of the plating layer may be 500 nm or greater and not greater than the thickness of the plating layer.

The thickness of the ceramic cover sheet may be 1 μm or greater and not greater than 30 μm.

The thickness of the plating layer may be greater than 4 μm and smaller than 15 μm.

According to another aspect of the present invention, there is provided a printed circuit board having an embedded multilayer ceramic electronic component therein, the printed circuit board including: an insulating substrate; and an embedded multilayer ceramic electronic component, including: a ceramic body including dielectric layers; first and second internal electrodes facing each other with the dielectric layers interposed therebetween; a first external electrode and a second external electrode formed on external surfaces of the ceramic body, the first external electrode being electrically connected to the first internal electrodes and the second external electrode being electrically connected to the second internal electrodes; and a plating layer formed on the first external electrode and the second external electrode, a surface roughness of the ceramic body being 500 nm or greater and not greater than a thickness of a ceramic cover sheet and a surface roughness of the plating layer being 300 nm or greater and not greater than a thickness of the plating layer.

The surface roughness of the ceramic body may be 700 nm or greater and not greater than the thickness of the ceramic cover sheet.

The surface roughness of the plating layer may be 500 nm or greater and not greater than the thickness of the plating layer.

The thickness of the ceramic cover sheet may be 1 μm or greater and not greater than 30 μm.

The thickness of the plating layer may be greater than 4 μm and smaller than 15 μm.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view showing an embedded multilayer ceramic electronic component according to an embodiment of the present invention;

FIG. 2 is a cross-sectional view taken along line B-B′ of FIG. 1;

FIG. 3 is an enlarged view of part A of FIG. 2;

FIG. 4 is a view showing a process of manufacturing an embedded multilayer ceramic electronic component according to an embodiment of the present invention; and

FIG. 5 is a cross-sectional view showing a printed circuit board having an embedded multilayer ceramic electronic component therein according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

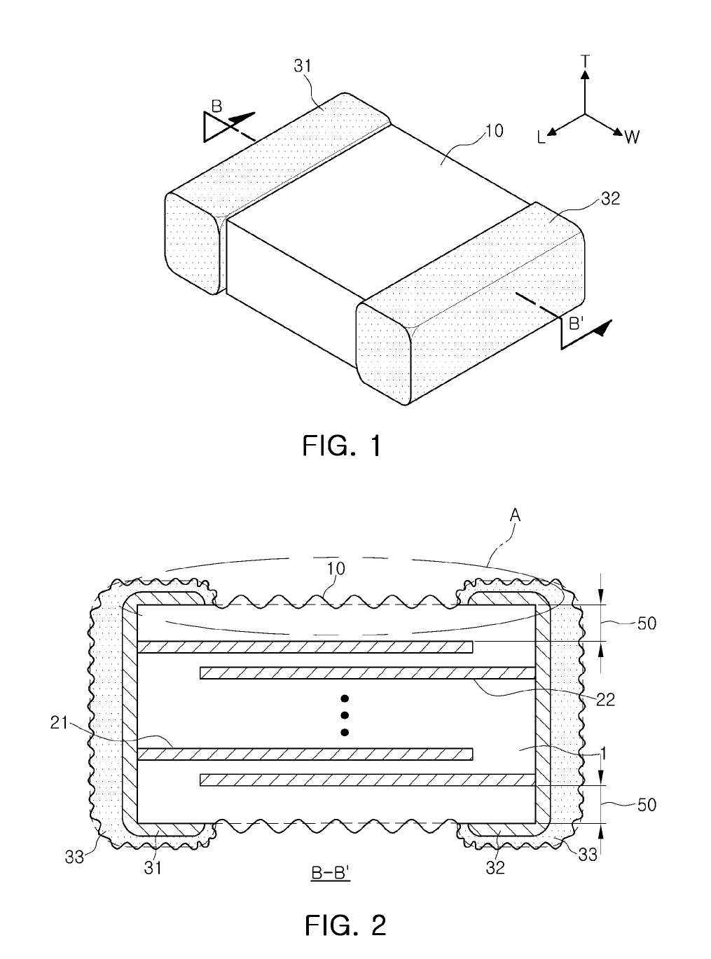

FIG. 1 is a perspective view showing an embedded multilayer ceramic electronic component according to an embodiment of the present invention.

FIG. 2 is a cross-sectional view taken along line B-B′ of FIG. 1.

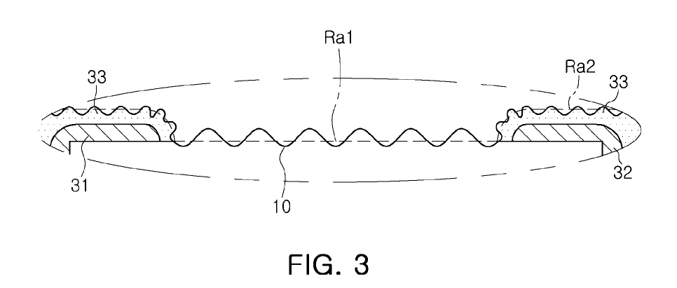

FIG. 3 is an enlarged view of part A of FIG. 2.

Referring to FIGS. 1 to 3, an embedded multilayer ceramic electronic component according to the embodiment of the invention may include: a ceramic body 10 including dielectric layers 1; first and second internal electrodes 21 and 22 facing each other with the dielectric layers 1 interposed therebetween; a first external electrode 31 and a second external electrode 32 formed on external surfaces of the ceramic body 10, the first external electrode 31 being electrically connected to the first internal electrodes 21 and the second external electrode 32 being electrically connected to the second internal electrodes 22; and a plating layer 33 formed on the first external electrode 31 and the second external electrode 32. Here, a surface roughness of the ceramic body 10 may be 500 nm or greater and not greater than a thickness of a ceramic cover sheet 50, and a surface roughness of the plating layer 33 may be 300 nm or greater and not greater than a thickness of the plating layer 33.

Hereinafter, the multilayer ceramic electronic component according to the embodiment of the invention, in particular, a multilayer ceramic capacitor, will be described, but the present invention is not limited thereto.

In the multilayer ceramic capacitor according to the embodiment of the invention, “a length direction”, “a width direction”, and “a thickness direction” will be defined as ‘L’ direction, ‘W’ direction, and ‘T’ direction, of FIG. 1. Here, the ‘thickness direction’ may be used in the same concept as a direction in which the dielectric layers are laminated, that is, ‘lamination direction’.

According to the embodiment of the invention, a raw material for forming the dielectric layers 1 is not particularly limited as long as sufficient capacitance can be obtained thereby. For example, the raw material may be a barium titanate (BaTiO₃) powder.

As a material for forming the dielectric layers 1, various ceramic additives, organic solvents, plasticizers, binders, dispersants, or the like may be added to powder, such as the barium titanate (BaTiO₃) powder, depending on the objects of the present invention.

The average particle diameter of ceramic powder used in forming the dielectric layers 1 is not particularly limited, and may be controlled in order to achieve objects of the present invention, for example, to 400 nm or lower.

A material for forming the first and second internal electrodes 21 and 22 is not particularly limited. For example, the first and second internal electrodes 21 and 22 may be formed by using a conductive paste composed of at least one of precious metal materials, such as, palladium (Pd), palladium-silver (Pd—Ag) alloy, and the like, nickel (Ni), and copper (Cu).

The first and second external electrodes 31 and 32 may be formed on external surfaces of the ceramic body 10 in order to form capacitance, and may be electrically connected to the first and second internal electrodes 21 and 22, respectively.

The first and second external electrodes 31 and 32 may be formed of the same conductive material as the first and second internal electrodes 21 and 22, but are not limited thereto. For example, the first and second external electrodes 31 and 32 may be formed of copper (Cu), silver (Ag), nickel (Ni), or the like.

The first and second external electrodes 31 and 32 may be formed by coating a conductive paste, which is prepared by adding glass frit to metal powder, followed by the firing thereof.

Referring to FIGS. 2 and 3, in the multilayer ceramic electronic component according to the embodiment of the invention, the surface roughness of the ceramic body 10 may be 500 nm to the thickness of the ceramic cover sheet 50, and the surface roughness of the plating layer 33 may be 300 nm to the thickness of the plating layer 33.

The ceramic body 10 may include a capacitance forming part contributing to capacitance formation and a cover layer provided on at least one surface of upper and lower surfaces of the capacitance forming part. The ceramic cover sheet may denote the cover layer, and the thickness of the ceramic cover sheet 50 may denote a thickness of the cover layer.

If the surface roughness of the ceramic body 10 is 500 nm or smaller and the surface roughness of the plating layer 33 is 300 nm or smaller, delamination between the multilayer ceramic electronic component and a printed circuit board may not be rectified. If the surface roughness of the ceramic body 10 is greater than the thickness of the ceramic cover sheet 50, and the surface roughness of the plating layer 33 is greater than the thickness of the plating layer 33, cracks may occur.

In addition, in the case in which the surface roughness of the ceramic body 10 is 700 nm or greater and not greater than the thickness of the ceramic cover sheet 50, and the surface roughness of the plating layer 33 is 500 nm or greater and not greater than the thickness of the plating layer 33, the delamination between the multilayer ceramic electronic component and the printed circuit board may be improved and cracks may be prevented.

The surface roughness is the degree of fine unevenness generated on a surface when a metal surface is processed, and is called surface profile. The surface roughness is generated by tools used in processing, depending on process suitability, and due to surface scratches, rust, or the like. With respect to the degree of roughness, when a surface of an element is cut perpendicularly thereto, a predetermined curve is shown in a cut cross-section thereof. The height from the lowest point of the curve to the highest point of the curve is taken, which is referred to as center line average roughness and expressed by Ra.

In the present invention, the surface roughness of the ceramic body 10 is designated by Ra₁ and the center line average roughness of the plating layer 33 is designated by Ra₂.

The thickness of the plating layer 33 may be greater than 4 μm and smaller than 15 μm.

If the case in which the thickness of the plating layer 33 is 4 μm, when the multilayer ceramic electronic component is embedded in a printed circuit board 100, there may occur a problem that a conductive via hole 140 is connected to the ceramic body 10 at the time of processing the conductive via hole 140. If the thickness of the plating layer 33 is 15 μm, cracks may occur in the ceramic body 10 due to stress of the plating layer 33.

The surface roughness of sandpaper may be transferred to a surface of the ceramic body 10 by placing the sandpaper on the surface of the ceramic body 10 at the time of a compressing process, and this is to generate surface roughness on the surface of the ceramic body 10. Here, the sandpaper may have a P value of 100 to 3000.

The ‘P’ of the sandpaper is a symbol for a particle size standard of the European Federation of European Producers of

Abrasives (FEPA) “P” grade.

FIG. 3 is a schematic view showing center line average roughness (Ra₁) of the ceramic body 10 and center line average roughness (Ra₂) of the plating layer 33.

Referring to FIG. 3, the multilayer ceramic electronic component according to the embodiment of the invention may satisfy 500 nm≦Ra₁≦thickness of ceramic cover sheet and 300 nm≦Ra₂≦thickness of plating layer, when the center line average roughness of the ceramic body 10 is designated by Ra₁ and the center line average roughness of the plating layer 33 is designated by Ra₂.

The center line average roughness of the ceramic body 10 (Ra₁) and the center line average roughness of the plating layer 33 (Ra₂) are values obtained by calculating the roughness of the ceramic body 10 and the plating layer 33 having a surface with roughness, and may mean roughnesses of the ceramic body 10 and the plating layer 33, which are respectively calculated by obtaining an average value based on an imaginary center line of the roughness.

Specifically, referring to FIG. 3, as for a method of calculating the center line average roughness of the ceramic body 10 (Ra₁) and the center line average roughness of the plating layer 33 (Ra₂), the imaginary center line may be drawn with respect to the roughness formed on one surface of each of the ceramic body 10 and the plating layer 33.

Then, respective distances based on the imaginary center line of the roughness (e.g., r₁, r₂, r₃ . . . r₁₃) are measured, and then an average value of the respective distances is calculated according to the following equation. Through the average value, the center line average roughness of the ceramic body 10 (Ra₁) and the center line average roughness of the plating layer 33 (Ra₂) may be determined.

$${R}_{a} = \frac{\vert {r}_{1} \vert + \vert {r}_{2} \vert + \vert {r}_{3} \vert + … \vert {r}_{n} \vert}{n}$$

A multilayer ceramic electronic component having excellent withstand voltage characteristics and improved adhesive strength with a printed circuit board may be realized, by controlling the center line average roughness of the ceramic body 10 (Ra₁) and the center line average roughness of the plating layer 33 (Ra₂) to satisfy 500 nm≦Ra₁≦thickness of ceramic cover sheet and 300 nm≦Ra₂≦thickness of plating layer, respectively.

In the multilayer ceramic electronic component according to another embodiment of the invention, overlapping descriptions with the multilayer ceramic electronic component according to the above-described embodiment of the invention will be omitted.

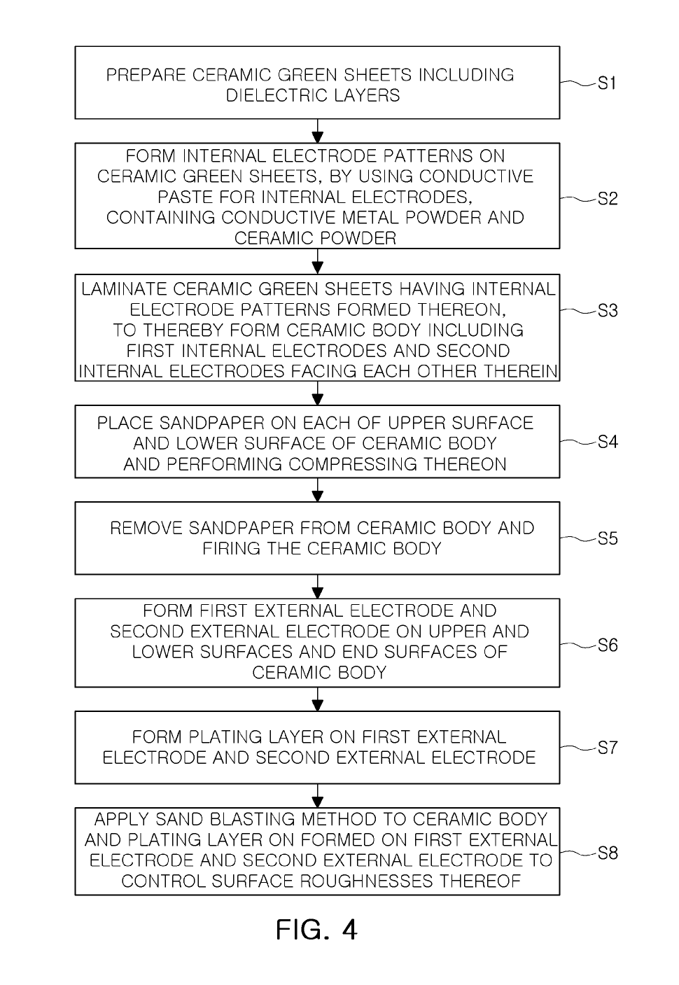

FIG. 4 is a view showing a process of manufacturing an embedded multilayer ceramic electronic component according to an embodiment of the present invention.

Referring to FIG. 4, there is provided a method of manufacturing an embedded multilayer ceramic electronic component according to an embodiment of the invention, the method including: preparing ceramic green sheets including dielectric layers 1 (S1); forming internal electrode patterns on the ceramic green sheets by using a conductive paste for internal electrodes containing a conductive metal powder and a ceramic powder (S2); laminating the ceramic green sheets having the internal electrode patterns formed thereon, to thereby form the ceramic body 10 including the first internal electrodes 21 and the second internal electrodes 22 facing each other therein (S3); placing sandpaper on each of an upper surface and a lower surface of the ceramic body 10 and performing compressing thereon (S4); removing the sandpaper from the ceramic body 10 and firing the ceramic body 10 (S5); forming the first external electrode 31 and the second external electrode 32 on the upper and lower surfaces and end surfaces of the ceramic body 10 (S6); forming a plating layer 33 formed on the first external electrode 31 and the second external electrode 32 (S7); and applying a sand blasting method to the ceramic body 10 and the plating layer 33 formed on the first external electrode 31 and the second external electrode 32 to control surface roughnesses thereof (S8). Here, a surface roughness of the ceramic body 10 may be 500 nm or greater and not greater than the thickness of the ceramic cover sheet, 50, and the surface roughness of the plating layer 33 may be 300 nm or greater and not greater than the thickness of the plating layer 33.

As for the method of manufacturing the multilayer ceramic electronic component according to the embodiment of the invention, first, a slurry prepared by including powder such as barium titanate (BaTiO₃) or the like is coated and dried on a carrier film, to thereby prepare a plurality of ceramic green sheets, and this allows formation of dielectric layers.

The ceramic green sheet may be prepared by mixing a ceramic powder, a binder, and a solvent to prepare the slurry, and molding the slurry into a sheet shape having a thickness of several μm using a doctor blade method.

The conductive metal powder may be at least one of silver (Ag), lead (Pd), platinum (Pt), nickel (Ni), and copper (Cu).

In addition, the ceramic body 10 may include barium titanate (BaTiO₃).

The placing of the sandpaper on each of the upper surface and the lower surface of the ceramic body 10 (S4) is provided to form the surface roughness of the ceramic body 10. When sandpaper having a P value of 100 to 3000 is applied, artificial roughness may be formed. In this case, since only the roughness of a part of the surface of the ceramic body 10 is increased, only the surface roughness of the ceramic body 10 may be formed without affecting reliability of the multilayer ceramic electronic component.

In the forming of the plating layer 33 on the first external electrode 31 and the second external electrode 32 (S6), the sand blasting method is applied in order to artificially form the surface roughness of the first external electrode 31 and the second external electrode 32 after the firing of the ceramic body 10 is completed. The sand blasting method may also increase only the surface roughness of the first external electrode 31 and the second external electrode 32, and thus does not affect reliability of the multilayer ceramic electronic component.

The other descriptions of the same features as the foregoing multilayer ceramic electronic component according to the embodiment of the present invention will be omitted.

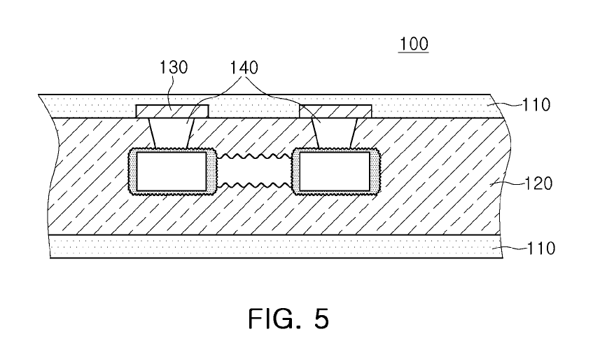

FIG. 5 is a cross-sectional view showing a printed circuit board having an embedded multilayer ceramic electronic component therein according to an embodiment of the present invention.

Referring to FIG. 5, there is provided the printed circuit board 100 having an embedded multilayer ceramic electronic component therein according to an embodiment of the invention, the printed circuit board including: an insulating substrate 110; and an embedded multilayer ceramic electronic component including: the ceramic body 10 including the dielectric layers 1; the first internal electrodes 21 and the second internal electrodes 22 disposed to face each other with the dielectric layers 1 interposed therebetween; the first external electrode 31 and the second external electrode 32 formed on external surfaces of the ceramic body 10, the first external electrode 31 being electrically connected to the first internal electrodes 21 and the second external electrode 32 being electrically connected to the second internal electrodes 22; and the plating layer 33 formed on the first external electrode 31 and the second external electrode 32. Here, a surface roughness of the ceramic body 10 may be 500 nm or greater and not greater than a thickness of the ceramic cover sheet and a surface roughness of the plating layer may be 300 nm or greater and not greater than a thickness of the plating layer.

The insulating substrate 110 may include an insulating layer 120, and, as necessary, may include a conductive pattern 130 and the conductive via hole 140 which constitute various types of interlayer circuits, as exemplified in FIG. 5. This insulting substrate 11 may be the printed circuit board 100 including a multilayer ceramic electronic component therein.

After being embedded in the printed circuit board 100, the multilayer ceramic electronic component is subjected to several severe environments during post processes such as thermal treatment and the like, in a similar manner to the printed circuit board 100. In particular, shrinkage and expansion of the printed circuit board 100 due to a thermal treatment process are directly transferred to the multilayer ceramic electronic component embedded in the printed circuit board 100, thereby applying stress to an adhesive surface between the multilayer ceramic electronic component and the printed circuit board 100. If the stress applied to the adhesive surface between the multilayer ceramic electronic component and the printed circuit board 100 is stronger than adhesive strength therebetween, delamination defects may occur, such as the adhesive surface may be delaminated.

The adhesive strength between the multilayer ceramic electronic component and the printed circuit board 100 is proportional to electrochemical binding force between the multilayer ceramic electronic component and the printed circuit board 100 and the effective surface area of the adhesive surface. Therefore, the delamination between the multilayer ceramic electronic component and the printed circuit board 100 can be reduced by controlling the surface roughness of the multilayer ceramic electronic component to increase the effective surface area of the adhesive surface between the multilayer ceramic electronic component and the printed circuit board 100. In addition, the frequency of delamination of the adhesive surface between the multilayer ceramic electronic component and the printed circuit board 100 depending on the surface roughness of the multilayer ceramic electronic component embedded in the printed circuit board 100 may be confirmed.

Hereafter, the present invention will be described in detail with reference to inventive examples, but is not limited thereto.

### INVENTIVE EXAMPLE 1

In order to confirm the frequency of delamination of the adhesive surface depending on the surface roughness of the embedded multilayer ceramic electronic component according to the embodiment of the invention, a board having a multilayer ceramic electronic component embedded therein is allowed to be left for 30 minutes and then the frequency of delamination was measured and investigated at a temperature of 85° C. and relative humidity of 85%, which corresponds to a general severe condition of a chip component for a mobile phone mother board (Severe Condition 1) and at a temperature of 125° C. and relative humidity of 85%, which corresponds to a severe condition according to higher functions of an application processor (AP) (Severe Condition 2) while the center line average roughness of the ceramic body 10 (Ra₁) and the center line average roughness of the plating layer 33 (Ra₂) were varied according to the thickness of the plating layer 33.

Experimental results in the case in which the thickness of the plating layer 33 was 5 μm were tabulated in Table 1; experimental results in the case in which the thickness of the plating layer 33 was 9 μm were tabulated in Table 2; and experimental results in the case in which the thickness of the plating layer 33 was 12 μm were tabulated in Table 3.

TABLE 1

| | |
|---|---|
| Surface Roughness, | Frequency of Delamination |
| Ra (nm) | of Adhesive Surface |

| Ceramic | Plating | Severe | Severe |
|---|---|---|---|
| Body | Layer | Condition 1 | Condition 2 |
| 200 | 200 | 2/500 | 29/500 |
| 300 | 200 | 2/500 | 12/500 |
| 400 | 200 | 1/500 | 5/500 |
| 500 | 300 | 0/500 | 2/500 |
| 600 | 400 | 0/500 | 1/500 |
| 700 | 500 | 0/500 | 0/500 |
| 800 | 600 | 0/500 | 0/500 |

TABLE 2

| | |
|---|---|
| Surface Roughness, | Frequency of Delamination |
| Ra (nm) | of Adhesive Surface |

| Ceramic | Plating | Severe | Severe |
|---|---|---|---|
| Body | Layer | Condition 1 | Condition 2 |
| 200 | 200 | 3/500 | 32/500 |
| 300 | 200 | 2/500 | 14/500 |
| 400 | 200 | 2/500 | 7/500 |
| 500 | 300 | 0/500 | 3/500 |
| 600 | 400 | 0/500 | 1/500 |
| 700 | 500 | 0/500 | 0/500 |
| 800 | 600 | 0/500 | 0/500 |

TABLE 3

| | |
|---|---|
| Surface Roughness, | Frequency of Delamination |
| Ra (nm) | of Adhesive Surface |

| Ceramic | Plating | Severe | Severe |
|---|---|---|---|
| Body | Layer | Condition 1 | Condition 2 |
| 200 | 200 | 5/500 | 27/500 |
| 300 | 200 | 4/500 | 13/500 |
| 400 | 200 | 4/500 | 5/500 |
| 500 | 300 | 0/500 | 2/500 |
| 600 | 400 | 0/500 | 2/500 |
| 700 | 500 | 0/500 | 0/500 |
| 800 | 600 | 0/500 | 0/500 |

As seen from Tables 1 to 3 above, it can be seen that, as the surface roughness of the ceramic body 10 and the plating layer 33 becomes lower, the frequency of delamination is increased, and thus it can be confirmed that the surface roughness of the multilayer ceramic electronic component can affect occurrence of delamination.

In order to prevent delamination between the multilayer ceramic electronic component and the printed circuit board 100 and pass the reliability standard in the sever condition for evaluation reliability of the chip component for a mobile phone mother board (Severe Condition 1), surface roughness values of the ceramic body 10 and the first and second external electrodes 31 and 32 need to satisfy 500 nm or greater and 300 nm or greater, respectively. In order to pass the more severe condition (Severe Condition 2), surface roughness values of the ceramic body 10 and the plating layer 33 need to satisfy 700 nm or greater and 500 nm or greater, respectively.

In the case in which the thickness of the plating layer 33 is 4 μm, there may occur a problem that the conductive via hole 140 is connected up to the ceramic body 10 at the time of processing the conductive via hole 140, and thus the effect of surface roughness was not confirmed. In the case in which the thickness of the plating layer 33 is 15 μm, cracks may occur in the ceramic body 10 due to stress of the plating layer 33. Therefore, the thickness of the plating layer 33 may satisfy 4 μm<thickness of plating layer<15 μm.

In addition, the surface roughness of the ceramic body 10 may not be thicker than the thickness of the ceramic cover sheet and the surface roughness of the plating layer 33 may not be thicker than the thickness of the plating layer 33, and thus, the maximum value of the surface roughness of the ceramic body 10 is limited to the thickness of the ceramic cover sheet 50, and the maximum value of the surface roughness of the plating layer 33 is limited to the thickness of the plating layer.

As set forth above, according to the embodiments of the present invention, the sandpaper is placed on the surface of the ceramic body at the time of compressing of the ceramic body, to thereby transfer the roughness of the sandpaper to the ceramic body, and then the external electrodes are plated to form the plating layer, so that the surface roughness of the ceramic surface of the multilayer ceramic electronic component and the surface roughness of the plating layer can be controlled, thereby rectifying the delamination between the multilayer ceramic electronic component and the printed circuit board and thus improving adhesive characteristics.

While the present invention has been shown and described in connection with the embodiments, it will be apparent to those skilled in the art that modifications and variations can be made without departing from the spirit and scope of the invention as defined by the appended claims.

What is claimed is:

1. An embedded multilayer ceramic electronic component, comprising:
a ceramic body including dielectric layers;
first and second internal electrodes facing each other with the dielectric layers interposed therebetween;
a first external electrode and a second external electrode formed on external surfaces of the ceramic body, the first external electrode being electrically connected to the first internal electrodes and the second external electrode being electrically connected to the second internal electrodes; and
a plating layer formed on the first external electrode and the second external electrode,
wherein a surface roughness of the ceramic body is 500 nm or greater and not greater than a thickness of a ceramic cover sheet and a surface roughness of the plating layer is 300 nm or greater and not greater than a thickness of the plating layer.

2. The embedded multilayer ceramic electronic component of claim 1, wherein the surface roughness of the ceramic body is 700 nm or greater and not greater than the thickness of the ceramic cover sheet.

3. The embedded multilayer ceramic electronic component of claim 1, wherein the surface roughness of the plating layer is 500 nm or greater and not greater than the thickness of the plating layer.

4. The embedded multilayer ceramic electronic component of claim 1, wherein the thickness of the ceramic cover sheet is 1 μm or greater and not greater than 30 μm.

5. The embedded multilayer ceramic electronic component of claim 1, wherein the thickness of the plating layer is greater than 4 μm and smaller than 15 μm.

6. A method of manufacturing an embedded multilayer ceramic electronic component, the method comprising:
preparing ceramic green sheets including dielectric layers;
forming internal electrode patterns on the ceramic green sheets by using a conductive paste for internal electrodes containing a conductive metal powder and a ceramic powder;
laminating the ceramic green sheets having the internal electrode patterns formed thereon, to thereby form a ceramic body including first internal electrodes and second internal electrodes facing each other therein;
placing sandpaper on each of an upper surface and a lower surface of the ceramic body and performing compressing thereon;
removing the sandpaper from the ceramic body and firing the ceramic body;
forming a first external electrode and a second external electrode on the upper and lower surfaces and end surfaces of the ceramic body;
forming a plating layer on the first external electrode and the second external electrode; and
applying a sand blasting method to the ceramic body and the plating layer formed on the first external electrode and the second external electrode to control surface roughnesses thereof,
wherein the surface roughness of the ceramic body is 500 nm or greater and not greater than a thickness of a ceramic cover sheet and the surface roughness of the plating layer is 300 nm or greater and not greater than a thickness of the plating layer.

7. The method of claim 6, wherein the surface roughness of the ceramic body is 700 nm or greater and not greater than the thickness of the ceramic cover sheet.

8. The method of claim 6, wherein the surface roughness of the plating layer is 500 nm or greater and not greater than the thickness of the plating layer.

9. The method of claim 6, wherein the thickness of the ceramic cover sheet is 1 μm or greater and not greater than 30 μm.

10. The method of claim 6, wherein the thickness of the plating layer is greater than 4 μm and smaller than 15 μm.

11. A printed circuit board having an embedded multilayer ceramic electronic component therein, the printed circuit board comprising:
an insulating substrate; and
an embedded multilayer ceramic electronic component, including: a ceramic body including dielectric layers; first and second internal electrodes facing each other with the dielectric layers interposed therebetween; a first external electrode and a second external electrode formed on external surfaces of the ceramic body, the first external electrode being electrically connected to the first internal electrodes and the second external electrode being electrically connected to the second internal electrodes; and a plating layer formed on the first external electrode and the second external electrode, a surface roughness of the ceramic body being 500 nm or greater and not greater than a thickness of a ceramic cover sheet and a surface roughness of the plating layer being 300 nm or greater and not greater than a thickness of the plating layer.

12. The printed circuit board of claim 11, wherein the surface roughness of the ceramic body is 700 nm or greater and not greater than the thickness of the ceramic cover sheet.

13. The printed circuit board of claim 11, wherein the surface roughness of the plating layer is 500 nm or greater and not greater than the thickness of the plating layer.

14. The printed circuit board of claim 11, wherein the thickness of the ceramic cover sheet is 1 μm or greater and not greater than 30 μm.

15. The printed circuit board of claim 11, wherein the thickness of the plating layer is greater than 4 μm and smaller than 15 μm.
